(19) United States
(12) Patent Application Publication
(10) Pub. No.: US 2019/0393084 A1
(43) Pub. Date: Dec. 26, 2019

(54) Method Utilizing Thermal Decomposition Material To Relax Queue Time Control

(71) Applicant: Tokyo Electron Limited, Tokyo (JP)

(72) Inventors: Yuki Kikuchi, Albany, NY (US); Toshiharu Wada, Albany, NY (US); Kaoru Maekawa, Albany, NY (US); Akiteru Ko, Albany, NY (US)

(21) Appl. No.: 16/446,572

(22) Filed: Jun. 19, 2019

Related U.S. Application Data
(60) Provisional application No. 62/689,296, filed on Jun. 25, 2018.
(60) Provisional application No. 62/714,051, filed on Aug. 2, 2018.

(51) Int. Cl. H01L 21/768; H01L 21/311

(52) U.S. Cl. CPC H01L 21/76831; H01L 23/5329; H01L 21/31127

(57) ABSTRACT

A process is provided in which low-k layers are protected from damage caused by exposure to atmospheric conditions by providing protection through the use of thermal decomposition materials. In one embodiment, the low-k layers may be low-k dielectric layers utilized in BEOL process steps. The thermal decomposition materials may be utilized to coat exposed regions of the low-k layers so that the low-k layers are not exposed to atmospheric conditions. In an exemplary embodiment, the low-k layers may be protected by plugging openings in the low-k layer with the thermal decomposition material. In another exemplary embodiment, trench and via openings in the low-k layer are plugged with the thermal decomposition material. The thermal decomposition materials may be removed by a heat based thermal anneal process step that does not damage the low-k layers.

This application claims priority to U.S. Provisional Patent Application No. 62/689,296 entitled, “Method Utilizing Thermal Decomposition Material To Relax Queue Time Control,” filed Jun. 25, 2018 and U.S. Provisional Patent Application No. 62/714,051 entitled, “Method Utilizing Thermal Decomposition Material To Relax Queue Time Control,” filed Aug. 2, 2018; the disclosures of which are expressly incorporated herein, in their entirety, by reference.

### BACKGROUND

The present disclosure relates to the processing of substrates. In particular, it provides a method for patterning of substrates.

As critical dimensions of features formed on substrates continue to shrink, the use of low dielectric constant (Low-k) materials (materials having a dielectric constant that is smaller than silicon dioxide) in substrate processing has become more important. Low-k materials may be used to form low-k layers that are utilized in a wide variety of points of a substrate process flow, including front end of line (FEOL) and back end of line (BEOL) process steps. It has been found, however, that if low-k layers are exposed to atmospheric conditions, low-k layers are susceptible to moisture absorption and particle growth. Such conditions not only impact the quality of the low-k layer but also may cause deterioration in subsequently formed films. For example, for low-k layers in which a trench and via are formed, metal layers that are subsequently deposited in the trench and via may be impacted by the moisture content and particles of the low-k layer. In such circumstances, it is necessary to carefully monitor queue time control between the process steps related to the formation of the trench and via and the metal deposition process steps so that the low-k layers are not exposed to atmospheric conditions for excessive time periods.

Thus, it would be desirable to utilize a more robust process flow in conjunction with low-k layers that relaxes the queue time control requirements.

### SUMMARY

In one embodiment, a process is provided in which low-k layers are protected from damage caused by exposure to atmospheric conditions by providing protection through the use of thermal decomposition materials. In one embodiment, the low-k layers may be low-k dielectric layers utilized in BEOL process steps. The thermal decomposition materials may be utilized to coat exposed regions of the low-k layers so that the low-k layers are not exposed to atmospheric conditions. In an exemplary embodiment, the low-k layers may be protected by plugging openings in the low-k layer with the thermal decomposition material. In another exemplary embodiment, trench and via openings in the low-k layer are plugged with the thermal decomposition material. The thermal decomposition materials may be removed by a thermal anneal process step that does not damage the low-k layers.

In another embodiment, a method of processing a substrate so as to extend a queue time between at least a first process step and a second process step is provided. The method comprises providing a first patterned layer on the substrate, the first patterned layer being sensitive to exposure to atmospheric conditions, the first patterned layer having a plurality surfaces. The method further comprises covering at least a portion of the plurality of surfaces with a thermal decomposition material, the thermal decomposition material allowing for an extended queue time between the first process step and the second process step. The method also comprises removing the thermal decomposition material by applying thermal energy to the thermal decomposition material.

In yet another embodiment, a method of processing a substrate so as to extend a queue time between at least a first process step and a second process step is provided. The method comprises providing a first layer on the substrate, the first layer having at least one exposed surface. The method also comprises protecting the at least one exposed surface from exposure to atmospheric conditions by providing a thermal decomposition material over the at least one exposed surface. The method further comprises utilizing the thermal decomposition material to extend an allowable queue time between the first process step and the second process step, the extending of the allowable queue time resulting from providing the thermal decomposition material over the at least one exposed surface. The method also comprises removing the thermal decomposition material by applying thermal energy to the thermal decomposition material.

In still yet another embodiment, a method of controlling a queue time in substrate processing is described. The method comprises providing a patterned low-k dielectric layer having a pattern on the substrate and performing a deposition of a thermal decomposition layer on the patterned low-k dielectric layer. The method further comprises removing a first portion of the thermal decomposition layer. The method also comprises removing a second portion of the thermal decomposition layer by applying thermal energy to the thermal decomposition layer; wherein a temperature of the substrate is 300 to 400 degrees C. According to the method, the queue time is controlled by timing a completion of the removing the second portion of the thermal decomposition layer and a beginning of a subsequent processing step.

### BRIEF DESCRIPTION OF THE DRAWINGS

A more complete understanding of the present inventions and advantages thereof may be acquired by referring to the following description taken in conjunction with the accompanying drawings, in which like reference numbers indicate like features. It is to be noted, however, that the accompanying drawings illustrate only exemplary embodiments of the disclosed concepts and are therefore not to be considered limiting of the scope, for the disclosed concepts may admit to other equally effective embodiments.

FIG. 1 illustrates an exemplary prior art structure for forming at least one trench and at least one via.

FIG. 2 illustrates the addition of a thermal decomposition layer to the structure of FIG. 1 in order to provide improved queue time control.

FIGS. 3-5 illustrate additional processing steps which may be performed on the structure of FIG. 2.

FIGS. 6-8 illustrate exemplary methods for using the techniques disclosed herein.

### DETAILED DESCRIPTION

A process is provided in which low-k layers are protected from damage caused by exposure to atmospheric conditions by providing protection through the use of thermal decomposition materials. In one embodiment, the low-k layers may be low-k dielectric layers utilized in BEOL process steps. The thermal decomposition materials may be utilized to coat exposed regions of the low-k layers so that the low-k layers are not exposed to atmospheric conditions. In an exemplary embodiment, the low-k layers may be protected by plugging openings in the low-k layer with the thermal decomposition material. In another exemplary embodiment, trench and via openings in the low-k layer are plugged with the thermal decomposition material. The thermal decomposition materials may be removed by a heat based thermal anneal process step that does not damage the low-k layers.

The heat based removal process for removing the thermal decomposition material is not limited to a specific heat based removal mechanism. For example, in one embodiment, thermal energy may be provided to the thermal decomposition material by providing thermal energy to the ambient surrounding the thermal decomposition material. In another embodiment, electromagnetic energy may be used to provide thermal energy to the thermal decomposition material. For example in one embodiment, a laser may be used to heat the thermal decomposition material. In another embodiment, microwave energy may be used to heat the thermal decomposition material. It will be recognized that other methods may be used to heat the thermal decomposition material such that a heat based removal mechanism is achieved.

As used herein, thermal decomposition material may decompose through, at least in part, the application of thermal energy to the material so that the material may be removed from the substrate via the application of the thermal energy. The thermal energy may be applied to the thermal decomposition material in a variety of manners. For example, heating of the ambient around the decomposition material is one manner of applying thermal energy. In another example, a laser, microwave or other electromagnetic energy may be used to create thermal energy in the thermal decomposition material.

The figures provided herein illustrate the use a thermal decomposition layer in a process flow that addresses low-k dielectric layer damage described above that may result from exposure of the low-k dielectric layer to atmospheric conditions. As shown in the figures, the exemplary use of this process may be BEOL trench and via process steps. As mentioned above, the techniques described herein are not, however, limited to a BEOL processes. Further, the techniques described herein are not limited to providing protection to a trench and via structure. In one embodiment, the layer protected from atmospheric conditions need not even be a patterned layer.

Further, the use of thermal decomposition materials to protect a layer from atmospheric exposure is not limited to the protection of low-k layers. Thus, it will be recognized that the techniques described herein may be utilized to protect a wide range of materials that are sensitive to atmospheric exposure. Thus, the techniques described herein are not limited to low-k materials or even dielectric materials, and the description of a particular application for protection of low-k dielectric layers will be recognized to be merely exemplary.

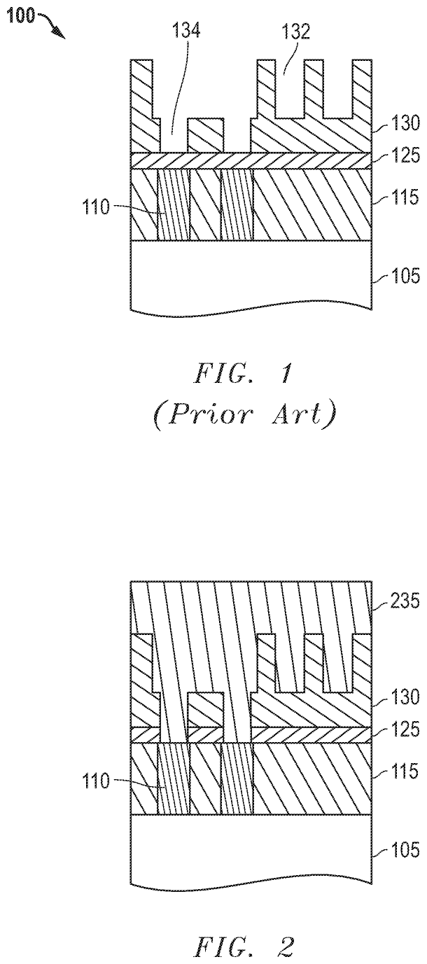

One embodiment of a process integration flow utilizing the thermal decomposition techniques described herein is shown in FIGS. 1-5. As shown in FIG. 1, a structure 100 is provided. The structure 100 includes a substrate 105. Substrate 105 may be any substrate for which the use of patterned features is desirable. For example, in one embodiment, substrate 105 may be a semiconductor substrate having one or more semiconductor processing layers formed thereon. In one embodiment, the substrate 105 may be a substrate that has been subject to multiple semiconductor processing steps which yield a wide variety of structures and layers, all of which are known in the substrate processing art. In one exemplary embodiment, the structure 100 may be used as part of trench and via formation technique utilized at a BEOL processing step for processing a semiconductor wafer.

The structure 100 of FIG. 1 has been patterned with trench and via patterns. As shown in FIG. 1, a first low-k dielectric layer 115 is provided over the substrate 105. In one embodiment, the first low-k dielectric layer 115 may be a porous low-k material such as an SiCHO material. However, it will be recognized that various types of low-k dielectric layers may be utilized, including but not limited to, doped silicon dioxides (fluorine, carbon and other dopants), spin-on polymers (including organic and silicon based polymers), porous oxides, etc., all being well-known in the art.

As shown in FIG. 1, a first conductor layer 110 may be formed in the first low-k dielectric layer 115. As shown in FIG. 1, a second low-k dielectric layer 130 has been patterned with a trench and via pattern to form trench regions 132 and via regions 134. An etch stop layer 125 may be located between the first low-k dielectric layer 115 and the second low-k dielectric layer 130. In one embodiment, the second low-k dielectric layer 130 may be formed of a material similar to the first low-k dielectric layer. In another embodiment, different types of low-k dielectrics may be utilized for the first low-k dielectric layer 115 and the second low-k dielectric layer 130. Any of a wide range of conductive materials may be used for the first conductor layer 110 including, but not limited to, copper, cobalt, or ruthenium. Any of a wide range of etch stop materials may be used for the etch stop layer 125, including, but not limited to, silicon carbon nitride (SiCN).

It will be recognized that the structure described herein in the figures is merely exemplary. Further, the structure 100 of FIG. 1 may be formed in a wide variety of manners with a wide variety of process flows, all as would be recognized by those skilled in the art, as the structure of FIG. 1 is conventional in the art. Thus, it will be recognized that the particular stack of layers shown in FIG. 1 is merely exemplary and many other variations of layers may be utilized while still obtaining the benefits of the use of a thermal decomposition material as described herein. For example, though the techniques are illustrated herein with regard to the patterning of the second low-k dielectric layer 130, it will be recognized that the techniques may also be utilized with regard to the patterning of the first low-k dielectric layer 115 or any other layers that are sensitive to atmospheric exposure.

The structure 100 of FIG. 1 may be similar to a wide variety of BEOL trench and/or via formation structures found in the substrate processing art. In conventional processing techniques, exposure of the structure 100 to atmospheric conditions would require careful queue time control between the formation of the trench and via patterns (for example an etch step) and the subsequently filling of those regions by use of a conductor formation step. The techniques described herein allow for such queue times to be expanded. Specifically, as shown in FIG. 2, a thermal decomposition layer 235 may be formed over the substrate 105, covering the exposed portions of the second low-k dielectric layer 130. As shown in FIG. 2, the thermal decomposition layer 235 is utilized to fill the trench regions 132 and via regions 134 and cover the exposed surfaces of the second low-k dielectric layer 130. The addition of the thermal decomposition layer 235 now provides a barrier such that the substrate 105 may be left in atmospheric conditions without significant further increases in the moisture absorption and particulate growth of the second low-k dielectric layer 130. The thermal decomposition layer 235 may be etched or planarized back as shown in FIG. 3 to form thermal decomposition layer portions 335. For example, a plasma etch may be used. In one embodiment, the plasma etch may be a nitrogen/hydrogen plasma etch.

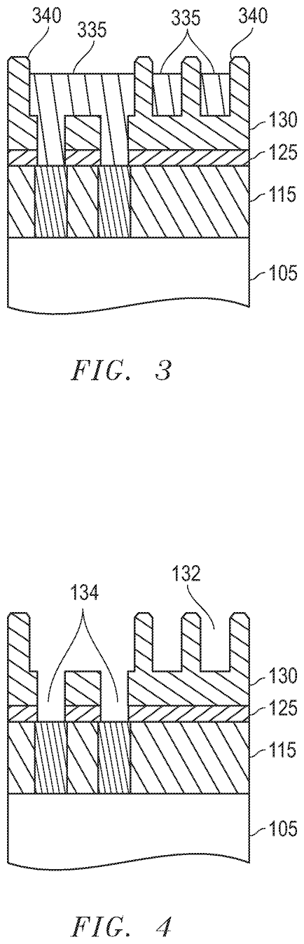

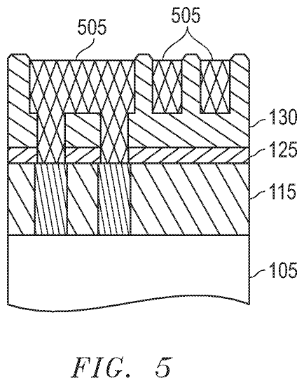

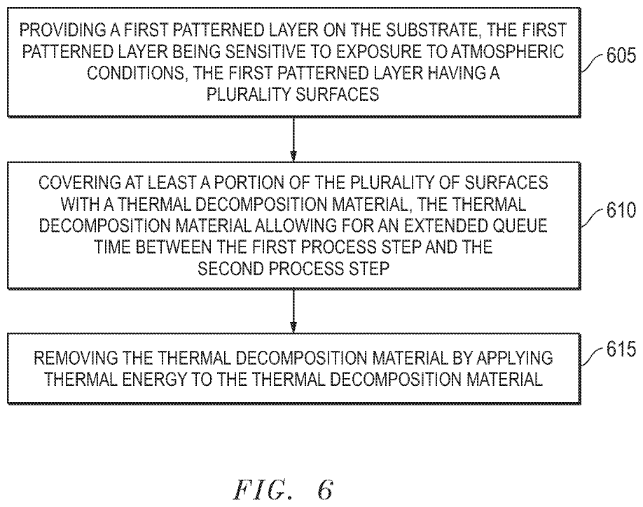

As shown in FIG. 3, the thermal decomposition layer portions 335 form a plurality of plugs which substantially fill the trench regions 132 and the via regions 134 and cover at least a portion of the exposed surfaces of the second low-k dielectric layer 130. Thus, the thermal decomposition material forms a plurality of plugs. It will be recognized that etching or planarizing the thermal decomposition layer 235 is optional. The presence of the thermal decomposition layer portions 335 suppresses damage to the second low-k dielectric layer 130 as much of the exposed sidewalls of the second low-k dielectric layer 130 are covered by the thermal decomposition layer portions 335. As shown in FIG. 3, the corners 340 of the second low-k dielectric layer 130 may be rounded to provide improvement in the formation of the conductor that will fill the trench and via. In one embodiment, the corner rounding may be accomplished through the use of a fluorocarbon based plasma. The corner rounding improves the subsequent conductor formation process (metal filling of the trench and vias). It will be recognized, however, that such corner rounding is optional. Then, as shown in FIG. 4, a thermal process may be utilized to remove the thermal decomposition layer portions 335 to again expose the trench regions 132 and via regions 134. After the processing as shown in FIGS. 2-4, standard processing techniques may be utilized to provide conductors in the trench and vias. Thus, as shown in FIG. 5, conductors 505 may be formed in the trench and vias. Though the exemplary embodiment described in the figures relates to the formation of plug like structures within an atmospheric sensitive material, it will be recognized that the formation of a thermal decomposition layer over an atmospheric sensitive material without forming plugs may also be utilized to achieve the benefits described herein. Thus, a plug-like filling process is not required. Further, it will be recognized that the techniques described herein may be utilized by merely providing a thermal decomposition layer over an unpatterned atmospheric sensitive layer.

It will be recognized that the techniques described herein are not limited to any particular planarization or etch back technique to achieve the structure shown in FIG. 3 as a wide range of techniques may be suitable. Further, a planarization or etch back such as shown in FIG. 3 need not even be performed. Rather, queue time improvements may be obtained merely by forming the thermal decomposition layer 235 over the substrate 105 such as shown in FIG. 2 without the etch back or planarization step of FIG. 3. In such case, when conductor formation is desired, processing may move directly from the structure of FIG. 2 to the structure of FIG. 4 by utilizing a thermal energy removal process to remove the thermal decomposition layer 235.

The techniques described with regard to FIGS. 2-5 are advantageous in that once the trench and via regions are filled with the thermal decomposition material, the queue time control requirements may in effect be suspended. Further, as the thermal anneal step is a relatively simple process step, the timing between the completion of removal of the thermal decomposition layer and the beginning of subsequent processing steps (in an exemplary embodiment, the conductor fill of the trench and via) may be more easily managed as compared to prior art queue control requirements. Further, as the thermal decomposition material may be removed through the use of merely a thermal anneal, a process which does not damage the low-k dielectric layer, other damage to the low-k dielectric layer is minimized.

In one embodiment, the queue time control between the formation of a structure such as shown in FIG. 1 and the conductor deposition shown in FIG. 5 in a prior art process without the usage of a thermal decomposition material as described herein may be limited to from two to six hours. However, by usage of the techniques described herein, the queue time between formation of a thermal decomposition material such as shown in FIG. 2 and the conductor deposition of FIG. 5 may be extended.

In order to further improve performance of the techniques described herein, one or more of the steps described above may be performed in-situ in a common process tool without exposure to atmosphere. For example, after formation of the trench and via regions of FIG. 1 through the use of an etch process in a process tool, rather than removing the substrate from the process tool, the process may directly move to a thermal decomposition material formation step in the same process tool so as to provide the structure as shown in FIG. 2. Such formation step may occur in the same process chamber or in a separate process chamber of the process tool. In either case, the etch and formation steps may be performed in an in-situ manner without exposing the substrate to an air break. In this manner, the exposure of the second low-k dielectric layer 130 to atmospheric conditions may be even further lessened. Similarly, the thermal anneal step performed to provide the structure shown in FIG. 4 may be performed in a common process tool as is utilized to subsequently form a conductor material in the trench regions 132 and via regions 134. However, it will be recognized that in-situ processing of the thermal decomposition material is not required, and exemplary usages of the techniques may be utilized whether or not in-situ processing occurs.

Thus, as described herein, the use of a thermal decomposition material to protect a material sensitive to atmospheric conditions (for example a low-k dielectric layer) from the effects of exposure to atmospheric conditions is described. After formation of the thermal decomposition material to protect the low-k dielectric layer, atmospheric exposure queue time requirements may be relaxed. Further, the formation of the thermal decomposition material may be performed in-situ in the same process tool as prior process steps (for example prior etch steps) so as to further add queue time flexibility. Likewise the removal of the thermal decomposition material may be performed in-situ in the same process tool as subsequent process steps (for example a conductor fill step) so as to further add queue time flexibility.

As mentioned above, the application of thermal energy may be achieved by a variety of manners, including but not limited to heating of the ambient around the thermal decomposition layer, by the use of lasers, by the use of microwaves, etc. Due to the nature of the thermal removal process, the removal of the thermal decomposition layer 235 may be achieved without causing damage to the second low-k dielectric layer 130.

In one exemplary embodiment, the thermal decomposition layer 235 may be removed by subjecting the layer to a heating process of less than 400° Celsius (C). In another embodiment, the heating process may be a process that heats the substrate in the range of 300°-400° C. and in a yet another embodiment, between 325°-375° C. In one embodiment, the thermal decomposition layer removal process may occur by applying heat for five minutes. It will be recognized, however, that other temperatures and times may be utilized.

The process described above may be used at a variety of process steps utilized in a substrate process flow. In one exemplary embodiment, the process described above may be part of a trench and via formation process. However, as mentioned above, the techniques described herein are not limited to trench and via formation processes.

Thus, it will be recognized that the concept of using a thermal decomposition material to protect portions of a low-k dielectric layer from exposure to atmospheric conditions is not limited to a trench and via process flows (such as shown in FIGS. 1-5). Therefore, it will be recognized that the techniques described herein may be utilized in a variety of semiconductor processing steps. In fact, it will be recognized that a wide range of process flows may utilize the techniques disclosed herein by covering regions of a substrate with a thermal decomposition material or creating layers of thermal decomposition material on a substrate for the purpose of protecting portions of another material that is sensitive to atmospheric exposure. The thermal decomposition materials may be removed merely through the use of thermal energy, a thermal process that may be utilized to remove the thermal decomposition material in a non-damaging fashion. Such techniques may be utilized at any of a wide variety of process steps which require the use of materials that are sensitive to atmospheric exposure.

In one embodiment, the thermal decomposition layer may be comprised of a material such a urea binding resin, specifically polyurea, which has depolymerizability and has characteristics that it can be removed by thermal treatment of less than 400° C., in another embodiment by thermal treatment in a process chamber to provide a substrate temperature between 300° C. and 400° C. is utilized. In another embodiment the thermal decomposition material is removed by thermal treatment of less than 300° C. Thus, through the application of thermal energy, the thermal decomposition material depolymerizes. By using such thermal decomposition materials, the exposure of low-k dielectric layer atmospheric conditions is reduced. Because the thermal decomposition layer can be removed by thermal treatment, the influence on the low-k dielectric layer of the removal process can be eliminated.

The techniques described herein are not limited to a particular thermal decomposition material, as a variety of materials may be utilized while still obtaining the benefit of utilizing a thermal removal process so that the atmospheric sensitive layer is not damaged. However, in one embodiment a urea binding resin may be utilized. One specific embodiment of such a urea binding resin is polyurea which may be formed via a thin film deposition. Exemplary techniques for the formation of a polyurea and the removal of such a polyurea by a depolymerization process to thermal decompose the polyurea are described in more detail in U.S. patent application Ser. No. 15/654,307 filed Jul. 19, 2017, entitled “Method of Fabricating Semiconductor Device, Vacuum Processing Apparatus and Substrate Processing Apparatus,” to Yatsuda et al., the disclosure of which is expressly incorporated herein by reference in its entirety. The techniques described in U.S. patent application Ser. No. 15/654,307 include, but are not limited to, copolymerizing isocyanate and amine as raw material monomers to form a urea bond, and as described, an exemplary a vapor deposition polymerization process may be utilized. As described in U.S. patent application Ser. No. 15/654,307, a liquid process may also be used to form the polyurea. Further, as described, the polyurea may be subsequently depolymerized to an amine and vaporized by the application of a thermal treatment. It will be recognized, however, that other formation processes and other removal processes may be utilized while still gaining the benefits of the use of a thermal decomposition layer and thermal removal of such layer as described herein. Further, it will be recognized that the techniques described herein are not limited to polyurea and other materials and/or combinations or variants of polyurea and other materials may be utilized.

It will be recognized that the process flow described above are merely exemplary, and many other processes and applications may advantageously utilize the techniques disclosed herein.

FIGS. 6-8 illustrate exemplary methods for use of the processing techniques described herein. It will be recognized that the embodiments of FIGS. 6-8 are merely exemplary and additional methods may utilize the techniques described herein. Further, additional processing steps may be added to the methods shown in the FIGS. 6-8 as the steps described are not intended to be exclusive. Moreover, the order of the steps is not limited to the order shown in the figures as different orders may occur and/or various steps may be performed in combination or at the same time.

In FIG. 6, a method of processing a substrate so as to extend a queue time between at least a first process step and a second process step is illustrated. The method comprises step 605 of providing a first patterned layer on the substrate, the first patterned layer being sensitive to exposure to atmospheric conditions, the first patterned layer having a plurality surfaces. The method further comprises step 610 of covering at least a portion of the plurality of surfaces with a thermal decomposition material, the thermal decomposition material allowing for an extended queue time between the first process step and the second process step. The method also comprises step 615 of removing the thermal decomposition material by applying thermal energy to the thermal decomposition material.

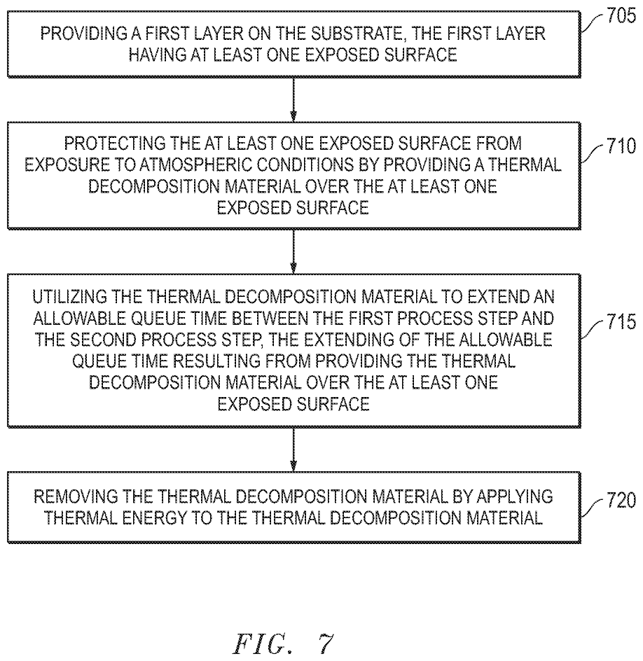

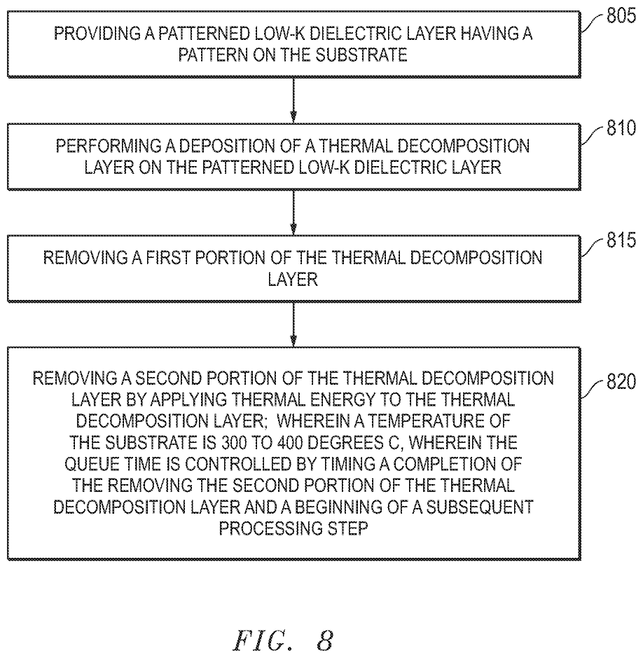

In FIG. 7, a method of processing a substrate so as to extend a queue time between at least a first process step and a second process step is illustrated. The method comprises step 705 of providing a first layer on the substrate, the first layer having at least one exposed surface. The method also includes step 710 of protecting the at least one exposed surface from exposure to atmospheric conditions by providing a thermal decomposition material over the at least one exposed surface. The method further comprises step 715 of utilizing the thermal decomposition material to extend an allowable queue time between the first process step and the second process step, the extending of the allowable queue time resulting from providing the thermal decomposition material over the at least one exposed surface. The method also comprises step 720 of removing the thermal decomposition material by applying thermal energy to the thermal decomposition material.

In FIG. 8, a method of controlling a queue time in substrate processing is illustrated. The method comprises step 805 of providing a patterned low-k dielectric layer having a pattern on the substrate. The method also comprises step 810 of performing a deposition of a thermal decomposition layer on the patterned low-k dielectric layer. The method further comprise step 815 of removing a first portion of the thermal decomposition layer. The method still further comprises step 820 of removing a second portion of the thermal decomposition layer by applying thermal energy to the thermal decomposition layer; wherein a temperature of the substrate is 300 to 400 degrees C., wherein the queue time is controlled by timing a completion of the removing the second portion of the thermal decomposition layer and a beginning of a subsequent processing step

Further modifications and alternative embodiments of the inventions will be apparent to those skilled in the art in view of this description. Accordingly, this description is to be construed as illustrative only and is for the purpose of teaching those skilled in the art the manner of carrying out the inventions. It is to be understood that the forms and method of the inventions herein shown and described are to be taken as presently preferred embodiments. Equivalent techniques may be substituted for those illustrated and described herein and certain features of the inventions may be utilized independently of the use of other features, all as would be apparent to one skilled in the art after having the benefit of this description of the inventions.

What is claimed is:

1. A method of processing a substrate so as to extend a queue time between at least a first process step and a second process step, the method comprising:
providing a first patterned layer on the substrate, the first patterned layer being sensitive to exposure to atmospheric conditions, the first patterned layer having a plurality surfaces;
covering at least a portion of the plurality of surfaces with a thermal decomposition material, the thermal decomposition material allowing for an extended queue time between the first process step and the second process step; and
removing the thermal decomposition material by applying thermal energy to the thermal decomposition material.

2. The method of claim 1, wherein the first patterned layer comprises a low-k dielectric.

3. The method of claim 2, wherein at least one trench and at least one via are formed in the first patterned layer.

4. The method of claim 3, wherein the covering at least a portion of the plurality of surfaces with the thermal decomposition material comprises providing a plug in the at least one trench and the at least one via.

5. The method of claim 2, wherein the first process step is an etch step that etches at least a portion of the first patterned layer and the second process step is a conductor formation step that fills at least a portion of the first patterned layer with a conductor.

6. The method of claim 2, wherein the thermal decomposition material depolymerizes through an application of thermal energy.

7. The method of claim 6, wherein the thermal decomposition material depolymerizes by a thermal treatment of between 300 to 400° C.

8. The method of claim 7, wherein the thermal decomposition material is comprised of a urea binding resin.

9. The method of claim 1, wherein the thermal decomposition material depolymerizes through an application of thermal energy.

10. The method of claim 9, wherein the thermal decomposition material depolymerizes by a thermal treatment of between 300 to 400° C.

11. The method of claim 10, wherein the thermal decomposition material is comprised of a urea binding resin.

12. A method of processing a substrate so as to extend a queue time between at least a first process step and a second process step, the method comprising:
providing a first layer on the substrate, the first layer having at least one exposed surface;
protecting the at least one exposed surface from exposure to atmospheric conditions by providing a thermal decomposition material over the at least one exposed surface;
utilizing the thermal decomposition material to extend an allowable queue time between the first process step and the second process step, the extending of the allowable queue time resulting from providing the thermal decomposition material over the at least one exposed surface; and
removing the thermal decomposition material by applying thermal energy to the thermal decomposition material.

13. The method of claim 12 wherein the second process step is a conductor formation step.

14. The method of claim 12, wherein the thermal decomposition material forms a plurality of plugs within the first layer.

15. The method of claim 14, wherein the thermal decomposition material is provided over the substrate and then at least a portion of the thermal decomposition material is removed to provide the plugs.

16. The method of claim 15 wherein the first layer is a low-k dielectric layer.

17. The method of claim 12, wherein the thermal decomposition material depolymerizes through an application of thermal energy.

18. The method of claim 17, wherein the thermal decomposition material is comprised of a urea binding resin.

19. A method of controlling a queue time in substrate processing, the method comprising:
providing a patterned low-k dielectric layer having a pattern on the substrate;
performing a deposition of a thermal decomposition layer on the patterned low-k dielectric layer;
removing a first portion of the thermal decomposition layer; and
removing a second portion of the thermal decomposition layer by applying thermal energy to the thermal decomposition layer; wherein a temperature of the substrate is 300 to 400 degrees C.;
wherein the queue time is controlled by timing a completion of the removing the second portion of the thermal decomposition layer and a beginning of a subsequent processing step.

20. The method of claim 19, wherein the subsequent processing step is a conductor fill step.
